(19) United States
(12) Patent Application Publication
(10) Pub. No.: US 2026/0096250 A1
(43) Pub. Date: Apr. 2, 2026

(54) LIGHT EMITTING DEVICE AND MANUFACTURING METHOD THEREOF

(71) Applicant: Japan Display Inc., Tokyo (JP)

(72) Inventors: Masanobu IKEDA, Tokyo (JP); Masumi NISHIMURA, Tokyo (JP)

(21) Appl. No.: 19/413,075

(22) Filed: Dec. 9, 2025

Related U.S. Application Data
(63) Continuation of application No. PCT/JP2024/017972, filed on May 15, 2024.

(30) Foreign Application Priority Data
Jul. 3, 2023 (JP) 2023-109627

(51) Int. Cl. H10H 20/82; H10H 20/01; H10H 20/812; H10H 20/825; H10H 20/855

(52) U.S. Cl. CPC H10H 20/82; H10H 20/01335; H10H 20/0363; H10H 20/812; H10H 20/825; H10H 20/855

(57) ABSTRACT

A light emitting device includes an ScAlMgO₄ substrate including a first surface and a second surface opposite the first surface, an undoped nitride semiconductor layer over the second surface of the ScAlMgO₄ substrate, and a light emitting layer over the undoped nitride semiconductor layer. The light emitting layer has an MQW structure in which well layers containing InₓGa₍₁₋ₓ₎N (0.30≤x≤0.50) and barrier layers containing In_{y}Ga_{(1-y)}N (0<y<x) are alternately stacked. A concave-convex pattern is provided over the first surface.

### CROSS-REFERENCE TO RELATED APPLICATIONS

This application is a Continuation of International Patent Application No. PCT/JP2024/017972, filed on May 15, 2024, which claims the benefit of priority to Japanese Patent Application No. 2023-109627, filed on Jul. 3, 2023, the entire contents of which are incorporated herein by reference.

### FIELD

An embodiment of the present invention relates to a light emitting device using a nitride semiconductor. Further, an embodiment of the present invention relates to a method for manufacturing a light emitting device using a nitride semiconductor.

### BACKGROUND

A nitride semiconductor such as GaN or InGaN is widely used as a light emitting layer with a multiple quantum well (MQW) structure in a blue or green light emitting diode. When a nitride semiconductor is used for the light emitting layer in a red light emitting diode, an In ratio in the nitride semiconductor needs to be increased. However, when the nitride semiconductor is deposited using metal organic chemical vapor deposition (MOCVD) at a high temperature, the high In ratio in the nitride semiconductor leads to phase separation and reduced luminous efficiency. Further, when the In ratio in the MQW structure is high, polarization occurs due to lattice strain between a well layer and a barrier layer. As a result, since current dependence due to the quantum-confined Stark effect occurs, an emission wavelength is shifted to a shorter wavelength.

In recent years, a light emitting diode using an ScAlMgO₄ substrate, which has a small lattice mismatch with a nitride semiconductor, has been developed (for example, see Japanese laid-open patent application No. 2020-9914).

### SUMMARY

A light emitting device according to an embodiment of the present invention includes an ScAlMgO₄ substrate including a first surface and a second surface opposite the first surface, an undoped nitride semiconductor layer over the second surface of the ScAlMgO₄ substrate, and a light emitting layer over the undoped nitride semiconductor layer. The light emitting layer has an MQW structure in which well layers containing InₓGa₍₁₋ₓ₎N (0.30≤x≤0.50) and barrier layers containing In_{y}Ga_{(1-y)}N (0<y<x) are alternately stacked. A concave-convex pattern is provided over the first surface.

A method for manufacturing a light emitting device according to an embodiment of the present includes the steps of forming a degassing prevention layer over a first surface of an ScAlMgO₄ support substrate, forming an undoped nitride semiconductor layer over a second surface of the ScAlMgO₄ support substrate opposite the first surface, and forming a light emitting layer having an MQW structure by alternately depositing well layers containing InₓGa₍₁₋ₓ₎N (0.30≤x≤0.50) and barrier layers containing In_{y}In_{y}Ga_{(1-y)}N (0<y<x) over the undoped nitride semiconductor layer using sputtering.

### BRIEF DESCRIPTION OF DRAWINGS

FIG. 1 is a schematic cross-sectional view showing a configuration of a light emitting device according to an embodiment of the present invention.

FIG. 2 is a schematic cross-sectional view showing a configuration of a light emitting layer of a light emitting device according to an embodiment of the present invention.

FIG. 3 is a flowchart illustrating a method for manufacturing a light emitting device according to an embodiment of the present invention.

FIG. 4 is a schematic cross-sectional view illustrating a method for manufacturing a light emitting device according to an embodiment of the present invention.

FIG. 5 is a schematic cross-sectional view illustrating a method for manufacturing a light emitting device according to an embodiment of the present invention.

FIG. 6 is a schematic cross-sectional view illustrating a method for manufacturing a light emitting device according to an embodiment of the present invention.

FIG. 7 is a schematic cross-sectional view illustrating a method for manufacturing a light emitting device according to an embodiment of the present invention.

FIG. 8 is a schematic cross-sectional view illustrating a method for manufacturing a light emitting device according to an embodiment of the present invention.

FIG. 9 is a schematic cross-sectional view illustrating a method for manufacturing a light emitting device according to an embodiment of the present invention.

FIG. 10 is a schematic cross-sectional view illustrating a method for manufacturing a light emitting device according to an embodiment of the present invention.

FIG. 11 is a schematic cross-sectional view illustrating a method for manufacturing a light emitting device according to an embodiment of the present invention.

FIG. 12 is a schematic cross-sectional view illustrating a method for manufacturing a light emitting device according to an embodiment of the present invention.

FIG. 13 is a schematic cross-sectional view illustrating a method for manufacturing a light emitting device according to an embodiment of the present invention.

FIG. 14 is a flowchart illustrating a cleavage process of an ScAlMgO₄ support substrate in a manufacturing method of a light emitting device according to an embodiment of the present invention.

FIG. 15 is a schematic cross-sectional view illustrating a cleavage process of an ScAlMgO₄ support substrate in a manufacturing method of a light emitting device according to an embodiment of the present invention.

FIG. 16 is a schematic cross-sectional view illustrating a cleavage process of an ScAlMgO₄ support substrate in a manufacturing method of a light emitting device according to an embodiment of the present invention.

FIG. 17 is a schematic cross-sectional view showing a configuration of a light emitting device according to an embodiment of the present invention.

FIG. 18 is a schematic cross-sectional view showing a configuration of a light emitting device according to an embodiment of the present invention.

### DESCRIPTION OF EMBODIMENTS

Even when a light emitting diode is manufactured using an ScAlMgO₄ substrate, the high In ratio in the nitride semiconductor film deposited by MOCVD leads to phase separation in the nitride semiconductor, resulting in a decrease in luminous efficiency.

In view of the above problems, an embodiment of the present invention can provide a light emitting device in which a decrease in the luminous efficiency of the light emitting layer is suppressed and light extraction efficiency is improved. Further, an embodiment of the present invention can provide a method for manufacturing a light emitting device in which a decrease in the luminous efficiency of the light emitting layer is suppressed and light extraction efficiency is improved.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification and the like, the expression “a includes A, B, or C,” “α includes any of A, B, or C,” “α includes one selected from a group consisting of A, B and C,” and the like does not exclude the case where a includes a plurality of combinations of A to C unless otherwise specified. Further, these expressions do not exclude the case where a includes other components.

In the present specification and the like, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the present specification and the like, terms such as “first,” “second,” or “third” attached to components are convenient terms used to distinguish each component, and have no further meaning unless otherwise explained.

In the present specification and the drawings, the same reference numerals may be used when multiple components are identical or similar in general, and reference numerals with an upper case letter of the alphabet may be used when the multiple components are distinguished. Further, reference numerals with a hyphen and a natural number may be used when multiple portions of one component are distinguished.

In the specification and the like, the terms “film” and “layer” can be optionally interchanged with one another.

In the specification and the like, the term “nitride semiconductor” refers to a semiconductor containing nitrogen in III-V group semiconductors. For example, the “nitride semiconductor” is gallium nitride (GaN) or indium gallium nitride (InGaN).

In the specification and the like, the term “undoped nitride semiconductor” refers to a nitride semiconductor to which no impurities are added. A nitride semiconductor to which impurities are added and which is imparted with electrical conductivity is described as a “p-type nitride semiconductor” or an “n-type nitride semiconductor.”

In the specification and the like, the term “light emitting device” refers to any device including a light emitting element. For example, the term “light emitting device” includes a lighting device that irradiates light to a specific location, and a display device that displays a visual image or video. Further, the term “light emitting device” may also consist of only a light emitting element (e.g., an LED chip).

The following embodiments can be combined with each other as long as there is no technical contradiction.

### First Embodiment

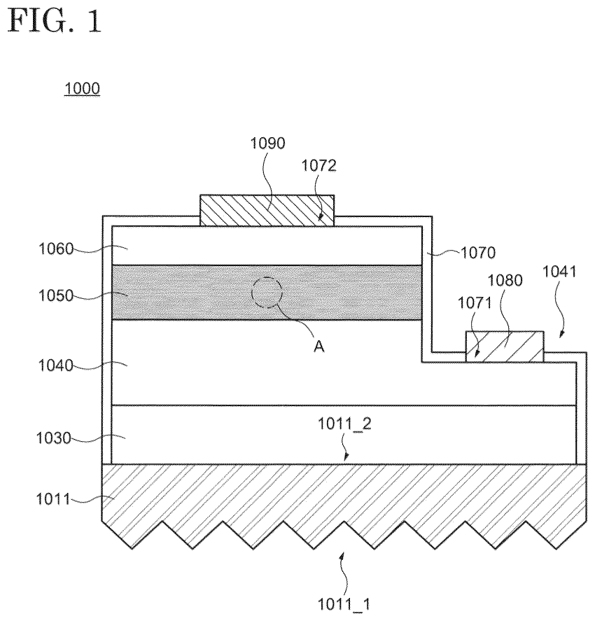

A light emitting device 1000 according to an embodiment of the present invention and a manufacturing method thereof are described with reference to FIGS. 1 to 16.

### [1. Configuration of Light Emitting Device 1000]

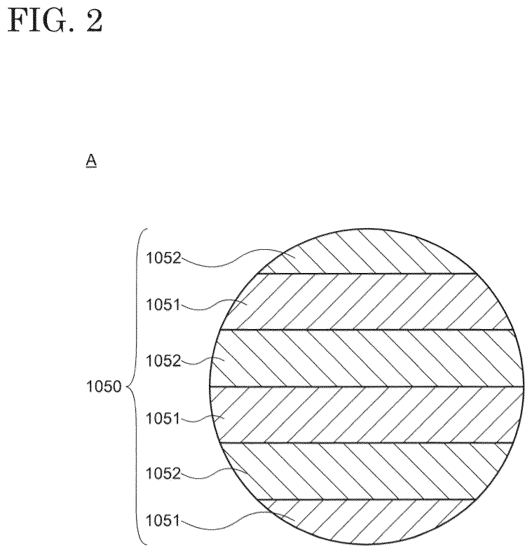

FIG. 1 is a schematic cross-sectional view showing a configuration of the light emitting device 1000 according to an embodiment of the present invention. FIG. 2 is a schematic cross-sectional view showing a configuration of a light emitting layer 1050 of the light emitting device 1000 according to an embodiment of the present invention. Specifically, FIG. 2 is a partially enlarged cross-sectional view of a region A shown in FIG. 1.

As shown in FIG. 1, the light emitting device 1000 includes an ScAlMgO₄ substrate 1011, an undoped nitride semiconductor layer 1030, an n-type nitride semiconductor layer 1040, a light emitting layer 1050, a p-type nitride semiconductor layer 1060, a protective layer 1070, an n-type electrode 1080, and a p-type electrode 1090.

A concave-convex pattern is formed on a first surface 1011_1 of the ScAlMgO₄ substrate 1011. The undoped nitride semiconductor layer 1030 is provided on and in contact with a second surface 1011_2 of the ScAlMgO₄ substrate 1011. The n-type nitride semiconductor layer 1040 is provided on and in contact with the undoped nitride semiconductor layer 1030. A recess 1041 recessed from an upper surface of the n-type nitride semiconductor layer 1040 is formed in the n-type nitride semiconductor layer 1040. The light emitting layer 1050 is provided on and in contact with the n-type nitride semiconductor layer 1040. The p-type nitride semiconductor layer 1060 is provided on and in contact with the light emitting layer 1050. The protective layer 1070 is provided so as to cover an edge surface of the undoped nitride semiconductor layer 1030, an edge surface of the n-type nitride semiconductor layer 1040, wall and bottom surfaces of the recesses 1041 in the n-type nitride semiconductor layer 1040, an edge surface of the light emitting layer 1050, and an edge and upper surface of the p-type nitride semiconductor layer 1060. The protective layer 1070 is provided with a first opening portion 1071 through which a portion of the bottom surface of the recesses 1041 (i.e., a portion of the n-type nitride semiconductor layer 1040 in the recesses 1041) is exposed and a second opening portion 1072 through which a portion of the top surface of the p-type nitride semiconductor layer 1060 is exposed. The n-type electrode 1080 is provided on and in contact with the n-type nitride semiconductor layer 1040 so as to cover the first opening portion 1071. The p-type electrode 1090 is provided on and in contact with the p-type nitride semiconductor layer 1060 so as to cover the second opening portion 1072.

### [1-1. ScAlMgO₄ Substrate 1011]

The ScAlMgO₄ substrate 1011 is a single crystal substrate made of an oxide (ScAlMgO₄) containing scandium (Sc), aluminum (AI), and magnesium (Mg). Since the lattice constant of ScAlMgO₄ is close to that of GaN, a lattice mismatch is small. Therefore, a GaN film deposited on the ScAlMgO₄ substrate 1011 has few defects and is a high-quality film. In particular, the lattice of the ScAlMgO₄ substrate is easy to match the lattice of In_{0.17}Ga_{0.83}N. In the ScAlMgO₄ substrate 1011, the c-axis of ScAlMgO₄ is oriented along the direction from the first surface 1011_1 to the second surface 1011_2. For example, the thickness of the ScAlMgO₄ substrate 1011 is greater than or equal to 5 μm and less than or equal to 10 μm. When the thickness of the ScAlMgO₄ substrate 1011 is within the above range, the amount of light emitted from an edge surface of the ScAlMgO₄ substrate 1011 can be reduced, and the extraction efficiency of light emitted from the first surface 1011_1 of the ScAlMgO₄ substrate 1011 can be improved.

The concave-convex pattern is formed on the first surface 1011_1 of the ScAlMgO₄ substrate 1011. Light emitted from the light emitting layer 1050 is emitted from the first surface 1011_1 of the ScAlMgO₄ substrate 1011. When the concave-convex pattern is formed on the first surface 1011_1, the light extraction efficiency can be improved. For example, the height of the concave-convex pattern is greater than or equal to 1 μm and less than or equal to 3 μm.

### [1-2. Undoped Nitride Semiconductor Layer 1030]

The undoped nitride semiconductor layer 1030 functions to improve the crystal quality of the n-type nitride semiconductor layer 1040 deposited on the undoped nitride semiconductor layer 1030. It is preferable to use a nitride semiconductor having the same composition as the n-type nitride semiconductor layer 1040 as the undoped nitride semiconductor layer 1030. Thus, since the lattice mismatch between the n-type nitride semiconductor layer 1040 and the undoped nitride semiconductor layer 1030 is decreased, it is possible to decrease the defects in the n-type nitride semiconductor layer deposited on the undoped nitride semiconductor layer 1030. For example, In_{0.17}Ga_{0.83}N can be used for the undoped nitride semiconductor layer 1030.

### [1-3. N-type Nitride Semiconductor Layer 1040]

The n-type nitride semiconductor layer 1040 has electron conductivity and functions to transport electrons to the light emitting layer 1050. The nitride semiconductor contained in the n-type nitride semiconductor layer 1040 is doped with impurities such as silicon (Si) or germanium (Ge). The impurities are activated in the nitride semiconductor to form the n-type nitride semiconductor layer 1040 having electron conductivity. For example, In_{0.17}Ga_{0.83}N doped with Si can be used for the n-type nitride semiconductor layer 1040. The thickness of the n-type nitride semiconductor layer 1040 is not limited to a certain value. For example, the thickness of the n-type nitride semiconductor layer 1040 is greater than or equal to 500 nm and less than or equal to 3000 nm.

As described above, the recess 1041 is formed in the n-type nitride semiconductor layer 1040. The depth of the recess 1041 is not limited to a certain value. For example, the depth of the recess 1041 is less than or equal to 300 nm from the upper surface of the n-type nitride semiconductor layer 1040.

### [1-4. Light Emitting Layer 1050]

The light emitting layer 1050 functions to recombine electrons transported from the n-type nitride semiconductor layer 1040 and holes transported from the p-type nitride semiconductor layer 1060 to emit light. As shown in FIG. 2, the light emitting layer 1050 has a so-called multiple quantum well (MQW) structure in which well layers 1051 and barrier layers 1052 are alternately stacked. Each of the well layers 1051 and the barrier layers 1052 is made of a nitride semiconductor. For example, InₓGa₍₁₋ₓ₎N can be used for the well layer 1051. In the present embodiment, the well layer 1051 contains a high ratio of In so that the light emitting device 1000 can emit light in the long-wavelength region of the visible light spectrum (e.g., yellow or red). Specifically, the value of x is greater than or equal to 0.30 and less than or equal to 0.50, preferably greater than or equal to 0.32 and less than or equal to 0.46, more preferably greater than or equal to 0.34 and less than or equal to 0.42, and particularly preferably greater than or equal to 0.36 and less than or equal to 0.40. A nitride semiconductor having a band gap larger than that of the nitride semiconductor of the well layer 1051 can be used for the barrier layer 1052. For example, InₓGa₍₁₋ₓ₎N (0<y<x) can be used for the barrier layer 1052.

### [1-5. P-type Nitride Semiconductor Layer 1060]

The p-type nitride semiconductor layer 1060 has hole conductivity and functions to transport holes to the light emitting layer 1050. The nitride semiconductor contained in the p-type nitride semiconductor layer 1060 is doped with impurities such as magnesium (Mg). The impurities are activated in the nitride semiconductor to form the p-type nitride semiconductor layer 1060 having hole conductivity. For example, In_{0.17}Ga_{0.83}N doped with Mg can be used for the p-type nitride semiconductor layer 1060. The thickness of the n-type nitride semiconductor layer 1040 is not limited to a certain value. For example, the thickness of the p-type nitride semiconductor layer 1060 is greater than or equal to 100 nm and less than or equal to 500 nm.

### [1-6. Protective Layer 1070]

The protective layer 1070 functions to suppress the entry of external impurities (e.g., moisture) and protect the undoped nitride semiconductor layer 1030, the n-type nitride semiconductor layer 1040, the light emitting layer 1050, and the p-type nitride semiconductor layer 1060. For example, silicon oxide, silicon nitride, or aluminum oxide can be used for the protective layer 1070. The protective layer 1070 may have a single layer structure or a stacked structure. For example, when the protective layer 1070 has a stacked structure, a stacked film (Al₂O₃/SiO₂) having an aluminum oxide film on a silicon oxide film can be used as the protective layer 1070. Further, a silicon nitride film (SiN) can be used as the protective layer 1070.

### [1-7. N-type Electrode 1080]

The n-type electrode 1080 functions to inject electrons into the n-type nitride semiconductor layer 1040. For example, a stacked structure (Au/Al/Ti) of titanium (Ti), aluminum (Al), and gold (Au) from the bottom up, or an alloy thereof, can be used for the n-type electrode 1080. The n-type electrode 1080 may have a single layer structure or a stacked structure.

### [1-8. P-type Electrode 1090]

The p-type electrode 1090 functions to inject holes into the p-type nitride semiconductor layer 1060. For example, a stacked structure of nickel (Ni) and gold (Au), a stacked structure of platinum (Pt) and gold (Au), a stacked structure of palladium (Pd) and gold (Au), indium tin oxide (ITO), chromium (Cr), or an alloy thereof can be used for the p-type electrode 1090. The p-type electrode 1090 may have a single layer structure or a stacked structure.

### [2. Manufacturing Method of Light Emitting Device 1000]

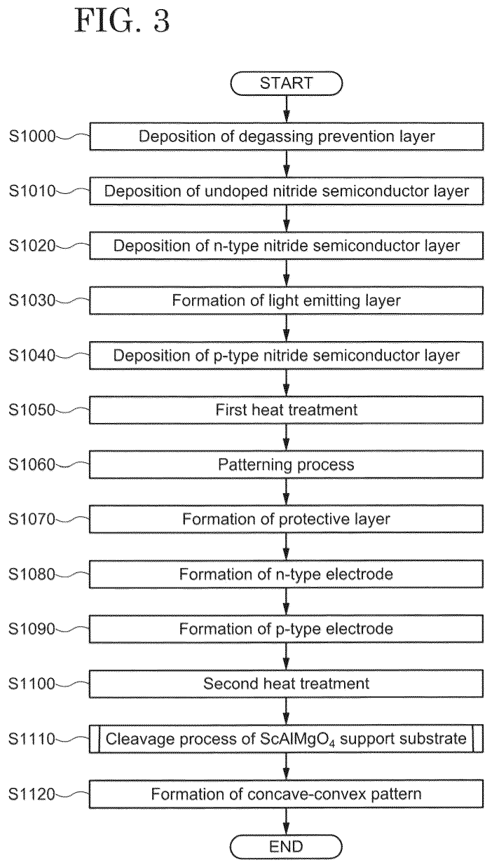

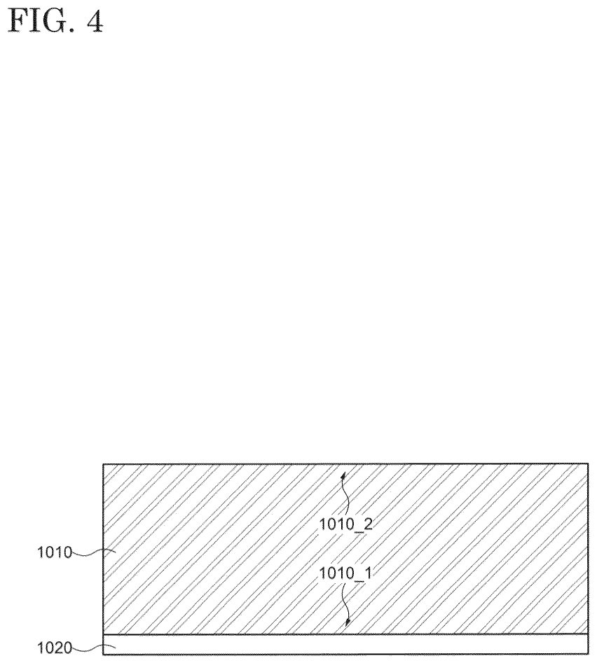

FIG. 3 is a flowchart illustrating a method for manufacturing the light emitting device 1000 according to an embodiment of the present invention. FIGS. 4 to 13 are schematic cross-sectional views illustrating a method for manufacturing the light emitting device 1000 according to an embodiment of the present invention.

As shown in FIG. 3, the method for manufacturing the light emitting device 1000 includes steps S1000 to S1120. Hereinafter, steps S1000 to S1120 are described in this order with reference to FIGS. 4 to 13.

In step S1000, a degassing prevention layer 1020 is deposited on the first surface 1010_1 of the ScAlMgO₄ support substrate 1010 (see FIG. 4). Although details are described later, the ScAlMgO₄ substrate 1011 is a part of the ScAlMgO₄ support substrate 1010. The degassing prevention layer 1020 may be damaged by, for example, scratches or chips on the first surface 1010_1 of the ScAlMgO₄ support substrate 1010 due to contact between the substrate stage and the ScAlMgO₄ support substrate 1010 during the substrate heating process in the deposition of the nitride semiconductor film in the manufacturing process of the light emitting device 1000. In this case, Mg in the ScAlMgO₄ support substrate 1010 is removed through the scratch or chip, and Mg becomes an impurity and is mixed into the nitride semiconductor film being deposited. Therefore, the degassing prevention layer 1020 is formed as a protective film on the first surface 1010_1 of the ScAlMgO₄ support substrate 1010 in order to prevent Mg loss. Thus, the occurrence of scratches or chips on the substrate can be suppressed. For example, aluminum nitride is used for the degassing prevention layer 1020. The degassing prevention layer 1020 can be deposited by chemical vapor deposition (CVD) or sputtering.

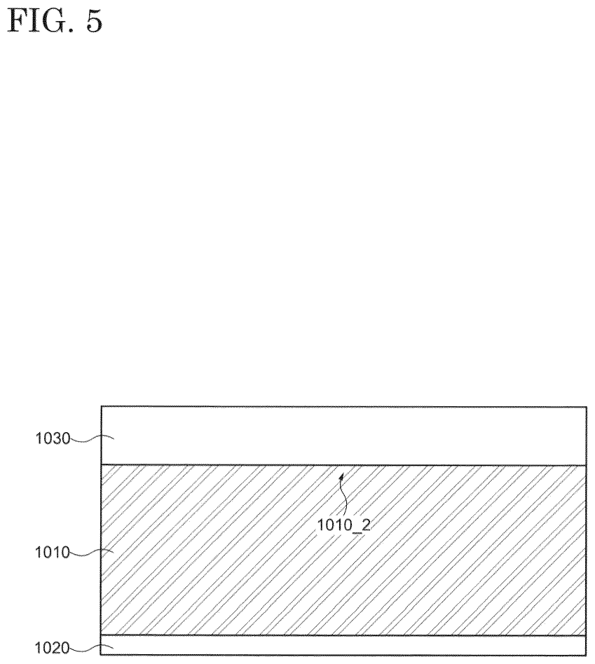

In step S1010, the undoped nitride semiconductor layer 1030 is deposited on a second surface 1010_2 opposite to the first surface 1010_1 of the ScAlMgO₄ support substrate 1010 (see FIG. 5). The undoped nitride semiconductor layer 1030 can be deposited by metal organic chemical vapor deposition (MOCVD) or atomic layer deposition (ALD).

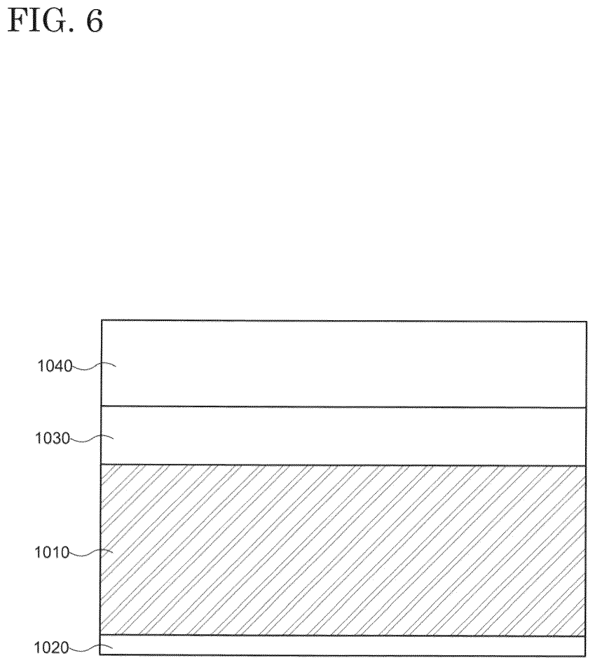

In step S1020, the n-type nitride semiconductor layer 1040 is deposited on the undoped nitride semiconductor layer 1030 (see FIG. 6). The n-type nitride semiconductor layer 1040 can be deposited by MOCVD, ALD, or the like.

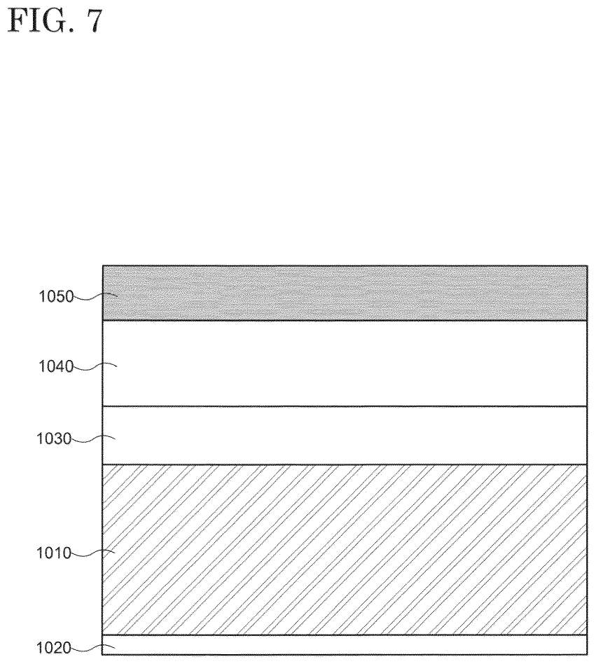

In step S1030, the light emitting layer 1050 is formed on the n-type nitride semiconductor layer 1040 (see FIG. 7). Specifically, the light emitting layer 1050 is formed by alternately depositing the nitride semiconductor well layers 1051 and the nitride semiconductor barrier layers 1052 by sputtering. In this way, the light emitting layer 1050 is formed by sputtering in the present embodiment. Since sputtering allows deposition at a lower temperature than MOCVD or ALD, the nitride semiconductor film deposited by sputtering can contain a high In composition. In other words, even when the nitride semiconductor film deposited by sputtering contains a high In composition, phase separation is unlikely to occur in the nitride semiconductor film. Therefore, the nitride semiconductor film of the light emitting layer 1050 has few crystal defects and is a high-quality film.

In depositing a nitride semiconductor film by sputtering, a nitride semiconductor can be used as a sputtering target, and nitrogen gas or a mixed gas of nitrogen and argon can be used as a sputtering gas. The sputtering may be RF sputtering or pulse sputtering.

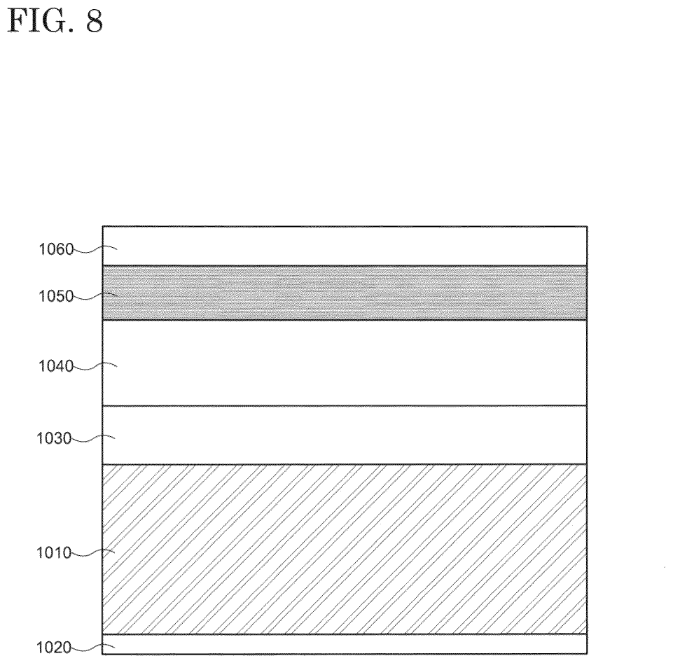

In step S1040, the p-type nitride semiconductor layer 1060 is deposited on the light emitting layer 1050 (see FIG. 8). The p-type nitride semiconductor layer 1060 can be deposited by MOCVD, ALD, or the like.

In step S1050, a first heat treatment is performed. The first heat treatment is a heat treatment mainly for activating impurities added to the nitride semiconductor of the p-type nitride semiconductor layer 1060. The first heat treatment improves the conductivity of the p-type nitride semiconductor layer 1060.

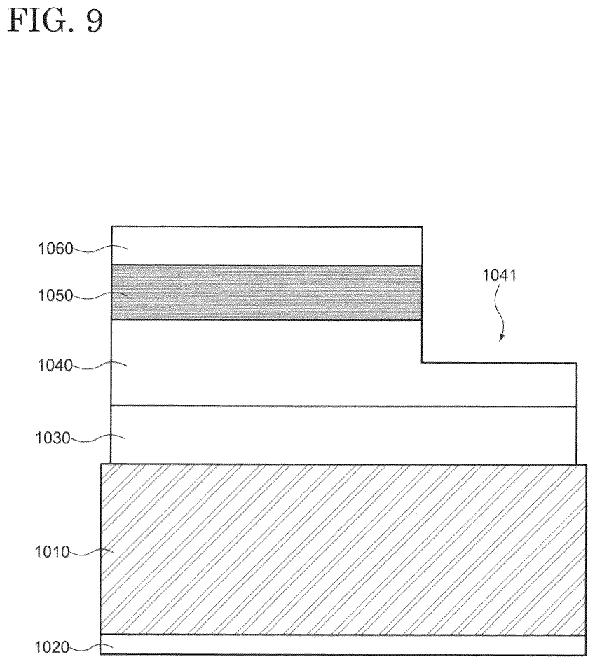

In step S1060, each layer deposited on the second surface 1010_2 of the ScAlMgO₄ support substrate 1010 is processed into a predetermined pattern shape (see FIG. 9). Specifically, the patterning process is performed by photolithography so that the edge surface of the undoped nitride semiconductor layer 1030, the edge surface of the n-type nitride semiconductor layer 1040, the edge surface of the light emitting layer 1050, and the edge surface of the p-type nitride semiconductor layer 1060 are exposed. Further, the recess 1041 is formed in the n-type nitride semiconductor layer 1040 in the patterning process.

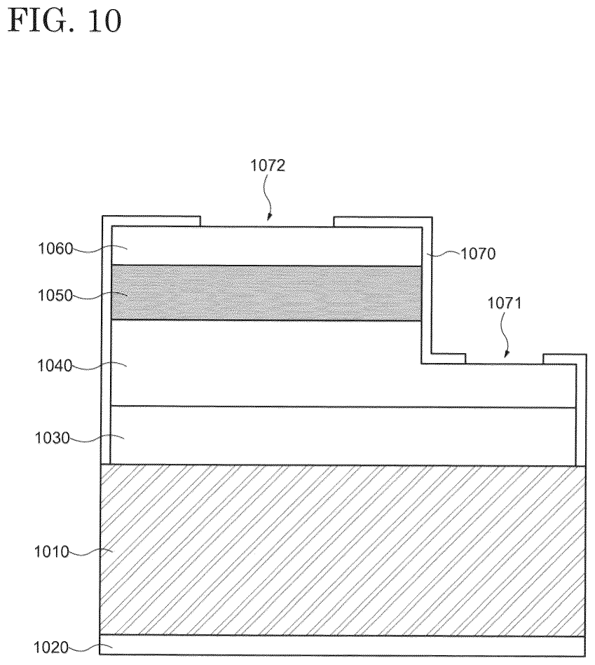

In step S1070, the protective layer 1070 is formed so as to cover the edge surface of the undoped nitride semiconductor layer 1030, the edge surface of the n-type nitride semiconductor layer 1040, the wall and bottom surfaces of the recess 1041 in the n-type nitride semiconductor layer 1040, the edge surface of the light emitting layer 1050, and the edge and top surfaces of the p-type nitride semiconductor layer 1060 (see FIG. 10). The protective layer 1070 can be deposited by electron beam evaporation, CVD, sputtering, or the like. Further, the first opening portion 1071 is formed in the protective layer 1070 by photolithography so as to expose the n-type nitride semiconductor layer 1040, and the second opening portion 1072 is formed so as to expose the p-type nitride semiconductor layer 1060.

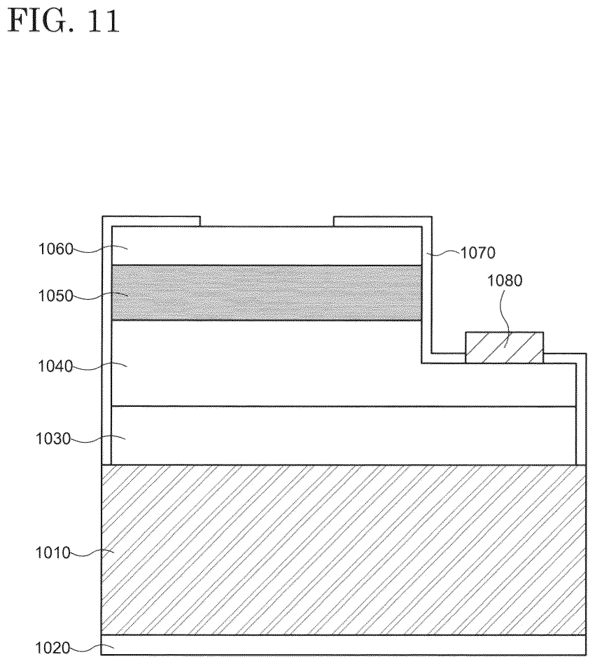

In step S1080, the n-type electrode 1080 is formed on the n-type nitride semiconductor layer 1040 so as to cover the first opening portion 1071 (see FIG. 11). The n-type electrode 1080 can be deposited by sputtering or the like. Further, the n-type electrode 1080 is processed into a predetermined pattern shape by photolithography. Furthermore, the n-type electrode 1080 may be formed using a lift-off method.

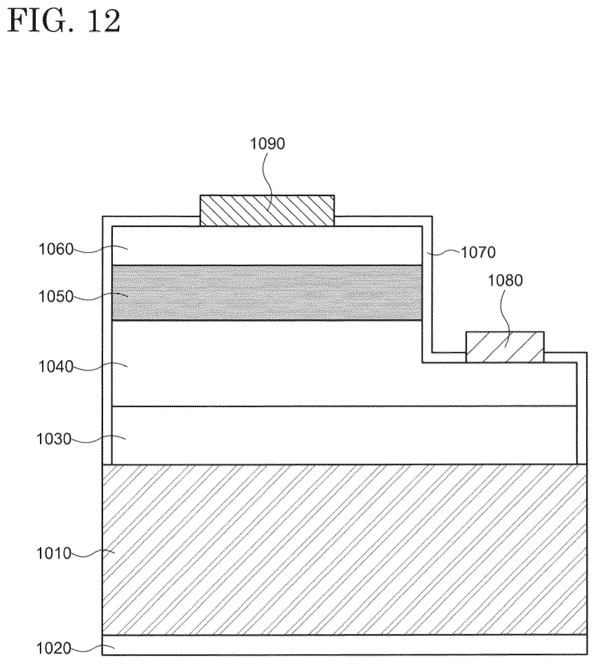

In step S1090, the p-type electrode 1090 is formed on the p-type nitride semiconductor layer 1060 so as to cover the second opening portion 1072 (see FIG. 12). The p-type electrode 1090 can be deposited by sputtering or the like. Further, the p-type electrode 1090 can be processed into a predetermined pattern shape by photolithography. Furthermore, the p-type electrode 1090 may be formed using a lift-off method.

In addition, steps S1080 and S1090 may be performed in the reverse order, and the n-type electrode 1080 may be formed after the p-type electrode 1090 is formed.

In step S1100, a second heat treatment is performed. The second heat treatment is a heat treatment mainly for improving the interfaces between the n-type nitride semiconductor layer 1040 and the n-type electrode 1080 and between the p-type nitride semiconductor layer 1060 and the p-type electrode 1090. The second heat treatment reduces the contact resistance between the n-type nitride semiconductor layer 1040 and the n-type electrode 1080 and between the p-type nitride semiconductor layer 1060 and the p-type electrode 1090.

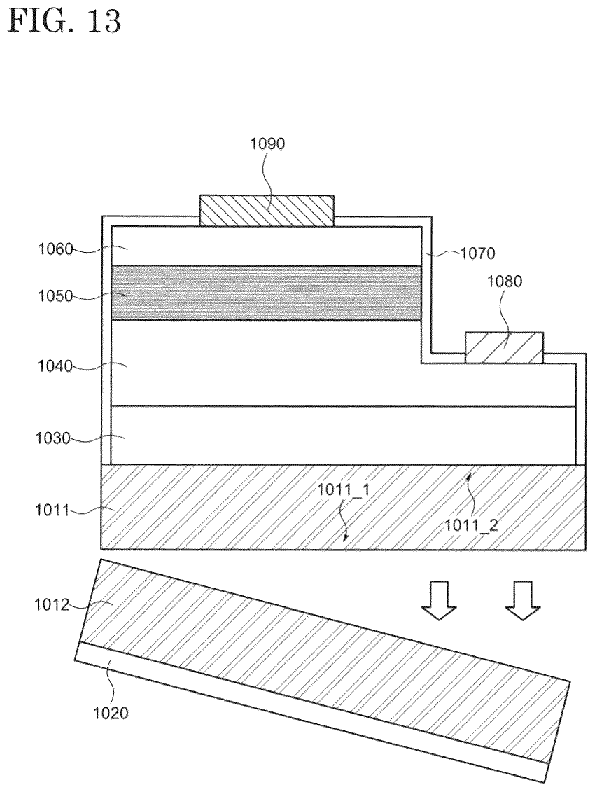

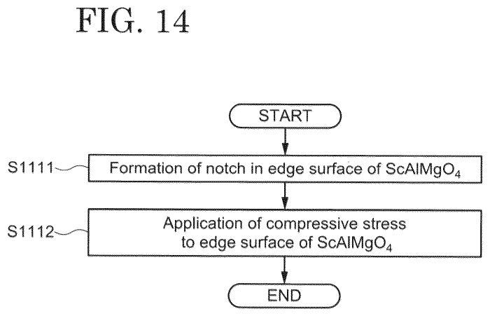

In step S1110, a cleavage process of the ScAlMgO₄ support substrate 1010 is performed (see FIG. 13). Step S1110 is described in detail with reference to FIGS. 14 to 16.

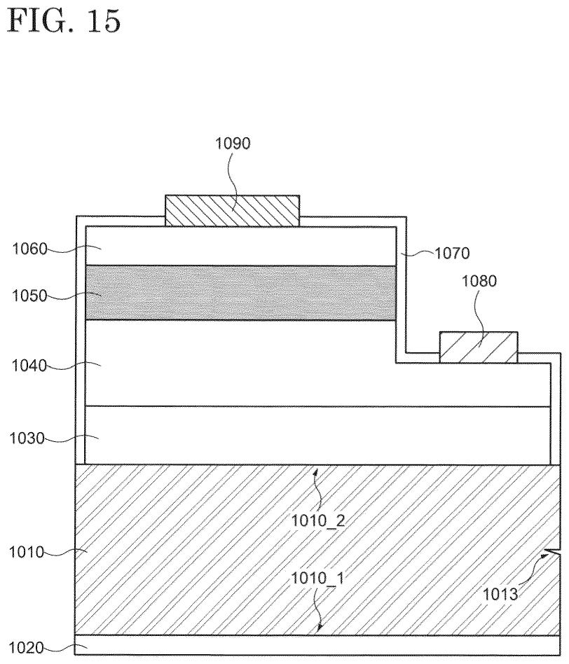

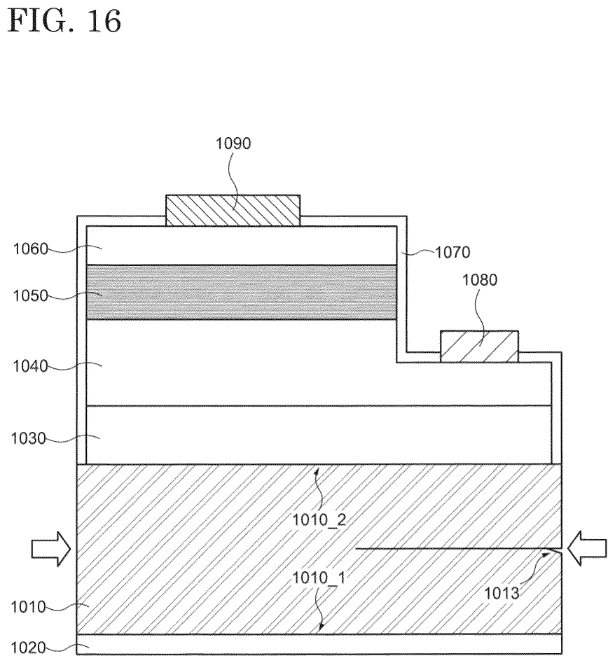

FIG. 14 is a flowchart illustrating the cleavage process of the ScAlMgO₄ support substrate 1010 in the manufacturing method of the light emitting device 1000 according to an embodiment of the present invention. FIGS. 15 and 16 are schematic cross-sectional views illustrating the cleavage process of the ScAlMgO₄ support substrate 1010 in the manufacturing method of the light emitting device 1000 according to an embodiment of the present invention.

In step S1111, a notch 1013 is formed in the edge surface of the ScAlMgO₄ support substrate 1010 (see FIG. 15). The notch 1013 is formed by pressing the tip of a diamond pen or cutter against a predetermined position on the edge surface of the ScAlMgO₄ support substrate 1010. Further, the notch 1013 may be formed by irradiating the edge surface of the ScAlMgO₄ support substrate 1010 with a laser.

In step S1112, compressive stress is applied to the edge surface of the ScAlMgO₄ support substrate 1010 (FIG. 16). ScAlMgO₄ has a cleavage plane parallel to its c-axis. In the ScAlMgO₄ support substrate 1010, the c-axis of ScAlMgO₄ is oriented along the direction from the first surface 1010_1 to the second surface 1010_2. Therefore, the ScAlMgO₄ support substrate 1010 is cleaved from the notch 1013 by applying compressive stress.

In the cleavage process of the ScAlMgO₄ support substrate 1010, particles may be generated during the formation of the notch 1013 and the cleavage of the ScAlMgO₄. Therefore, it is preferable to protect the second surface 1010_2 side of the ScAlMgO₄ support substrate 1010. For example, each layer on the second surface 1010_2 of the ScAlMgO₄ support substrate 1010 can be protected by applying a resist to the second surface 1010_2 side of the ScAlMgO₄ support substrate 1010 or by attaching a resist film to form a resist layer.

By the cleavage process of the ScAlMgO₄ support substrate 1010 described above, the ScAlMgO₄ support substrate 1010 is separated into the ScAlMgO₄ substrate 1011 and an ScAlMgO₄ substrate 1012 (see FIG. 13). The ScAlMgO₄ substrate 1011 with the degassing prevention layer 1020 formed thereon is removed, and the first surface 1011_1 of the ScAlMgO₄ substrate 1011 is revealed (the second surface 1011_2 of the ScAlMgO₄ substrate 1011 corresponds to the second surface 1010_2 of the ScAlMgO₄ support substrate 1010). The ScAlMgO₄ substrate 1011 with the degassing prevention layer 1020 formed thereon can be reused as the ScAlMgO₄ support substrate 1010 for manufacturing another light emitting device 1000.

In step S1120, a concave-convex pattern is formed on the first surface 1011_1 of the ScAlMgO₄ substrate 1011. The concave-convex pattern is formed by photolithography. When a resist layer is formed on the second surface 1011_2 side of the ScAlMgO₄ substrate 1011 during the cleavage process of the ScAlMgO₄ support substrate 1010, step S1120 can be performed without removing the resist layer in step S1110. When a resist layer is formed on the second surface 1011_2 side of the ScAlMgO₄ substrate 1011, each layer on the second surface 1011_2 side of the ScAlMgO₄ substrate 1011 can be protected during etching of the concave-convex pattern. ScAlMgO₄ can be etched using hydrofluoric acid. Al₂O₃ has high etching resistance to hydrofluoric acid. That is, Al₂O₃ is difficult to etch with hydrofluoric acid. Therefore, when the protective layer 1070 contains Al₂O₃, each layer on the second surface 1011_2 side of the ScAlMgO₄ substrate 1011 can be sufficiently protected.

Although the method for manufacturing the light emitting device 1000 is described based on the flowcharts shown in FIGS. 3 and 14, the method for manufacturing the light emitting device 1000 is not limited to the steps shown in the flowcharts of FIGS. 3 and 14. The light emitting device 1000 may be manufactured using a manufacturing method in which the order of steps S1000 to S1120 is interchanged, or may be manufactured using a manufacturing method that includes steps other than steps S1000 to S1120.

In addition, although descriptions are omitted, not only the light emitting layer 1050 but also one or more of the undoped nitride semiconductor layer 1030, the n-type nitride semiconductor layer 1040, and the p-type nitride semiconductor layer 1060 may be deposited by sputtering. In this case, since the undoped nitride semiconductor layer 1030, the n-type nitride semiconductor layer 1040, and the p-type nitride semiconductor layer 1060 can be deposited at low temperatures, the In ratio of the nitride semiconductors contained in the undoped nitride semiconductor layer 1030, the n-type nitride semiconductor layer 1040, and the p-type nitride semiconductor layer 1060 can be increased.

Further, although not shown in the figures, a buffer layer may be provided on the second surface 1010_2 of the ScAlMgO₄ support substrate 1010. When the undoped nitride semiconductor layer 1030 includes a nitride semiconductor with a high In ratio that is deposited by sputtering, it is possible to control the c-axis orientation of the undoped nitride semiconductor layer 1030 by providing the buffer layer. Since the undoped nitride semiconductor layer 1030 is provided on the buffer layer, either a conductive material or an insulating material may be used as the buffer layer. The buffer layer is deposited by CVD or sputtering.

For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th) can be used as the conductive material for the buffer layer. In particular, it is preferable to use Ti, graphene, or ZnO as the material for the buffer layer.

Further, silicon (Si), germanium (Ge), or an alloy thereof may be used as the conductive material for the buffer layer. Although silicon and germanium are semiconductor materials, silicon and germanium have higher conductivity than insulating materials, which are described later. Therefore, in the present specification, semiconductor materials such as silicon and germanium used as the buffer layer are described as conductive materials.

Further, for example, aluminum nitride (AlN), aluminum oxide (Al₂O₃), lithium niobate (LiNbO), BiLaTiO, SrFeO, BiFeO, BaFeO, ZnFeO, PMnN-PZT, or biological apatite (BAp) can be used as the insulating material for the buffer layer. In particular, it is preferable to use AlN for the buffer layer.

In the embodiment, since the light emitting layer 1050 is formed by sputtering, which allows for film formation at a low temperature, phase separation in the nitride semiconductor of the light emitting layer 1050 can be suppressed and the In ratio in the nitride semiconductor can be increased. Therefore, the light emitting device 1000 can emit red light from the light emitting layer 1050 containing a nitride semiconductor. Further, even when the light emitting device 1000 emits red light, the high crystal quality of the light emitting layer 1050 suppresses a decrease in the light emitting efficiency of the light emitting device 1000. Furthermore, the concave-convex pattern that improves light extraction efficiency is formed on the first surface 1011_1 of the ScAlMgO₄ substrate 1011, from which light is emitted from the light emitting device 1000. Therefore, the light emitting device 1000 according to the present embodiment improves light extraction efficiency.

### Second Embodiment

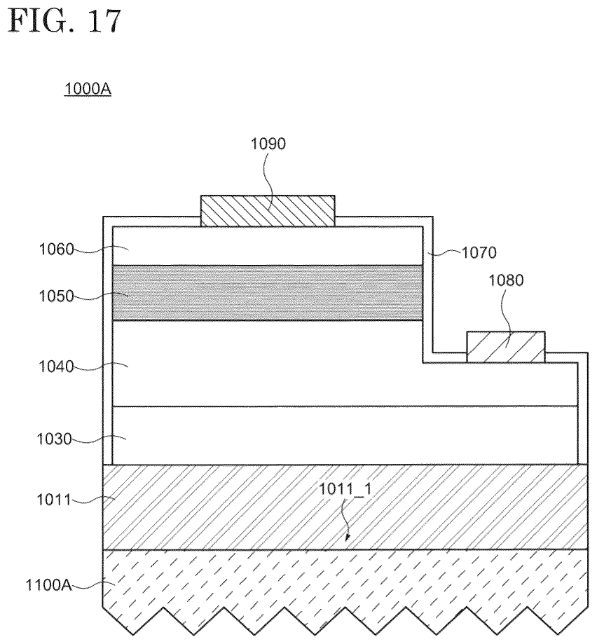

A light emitting device 1000A according to an embodiment of the present invention is described with reference to FIG. 17. In addition, hereinafter, when a configuration of the light emitting device 1000A is similar to the configuration of the light emitting device 1000, the description of the configuration of the light emitting device 1000A may be omitted.

FIG. 17 is a schematic cross-sectional view showing a configuration of the light emitting device 1000A according to an embodiment of the present invention.

As shown in FIG. 17, the light emitting device 1000A includes the ScAlMgO₄ substrate 1011, an optical adjustment layer 1100A, the undoped nitride semiconductor layer 1030, the n-type nitride semiconductor layer 1040, the light emitting layer 1050, the p-type nitride semiconductor layer 1060, the protective layer 1070, the n-type electrode 1080, and the p-type electrode 1090.

The optical adjustment layer 1100A is provided on the first surface 1011_1 of the ScAlMgO₄ substrate 1011. For example, silicon oxide (refractive index 1.46), polysiloxane (refractive index 1.43), or polysilazane (refractive index 1.55) can be used for the optical adjustment layer 1100A. The surface of the optical adjustment layer 1100A has a concave-convex pattern. The concave-convex pattern can be formed by photolithography after the optical adjustment layer 1100A is deposited.

The optical adjustment layer 1100A can be deposited by CVD or sputtering when it is made of a low molecular weight material such as silicon oxide, or by coating when it is made of a high molecular weight material such as polysiloxane or polysilazane.

The optical adjustment layer 1100A has a refractive index lower than the ScAlMgO₄ substrate 1011, and functions to improve the extraction efficiency of light that passes through the optical adjustment layer 1100A from the ScAlMgO₄ substrate 1011 and is emitted to the outside.

In the present embodiment, light emitted from the light emitting layer 1050 passes through the n-type nitride semiconductor layer 1040, the undoped nitride semiconductor layer 1030, the ScAlMgO₄ substrate 1011, and the optical adjustment layer 1100A before being emitted to the outside. The refractive indexes of the layers through which light passes can be set in the approximately smaller order of 2.3 (refractive index of the n-type nitride semiconductor layer 1040 and the undoped nitride semiconductor layer 1030), 1.9 (refractive index of the ScAlMgO₄ substrate 1011), and 1.4 to 1.6 (refractive index of the optical adjustment layer 1100A). Further, the concave-convex pattern that improves light extraction efficiency is formed on the surface of the optical adjustment layer 1100A. Therefore, the light emitting device 1000A according to the present embodiment improves light extraction efficiency.

### Third Embodiment

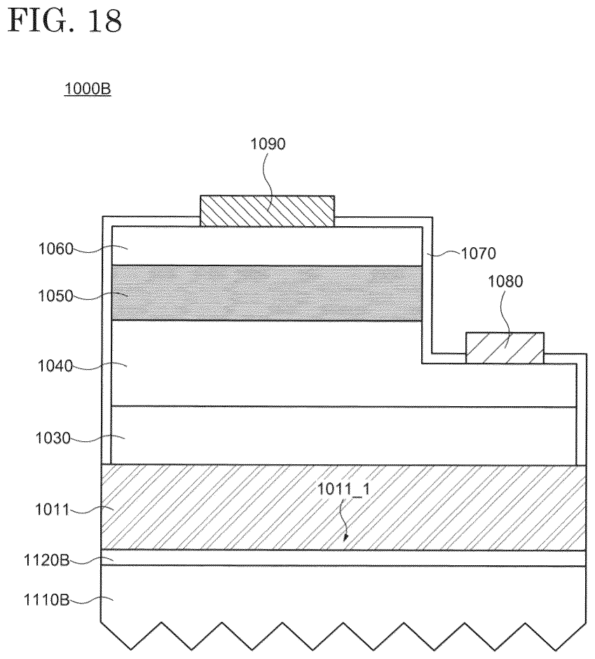

A light emitting device 1000B according to an embodiment of the present invention is described with reference to FIG. 18. In addition, hereinafter, when a configuration of the light emitting device 1000B is similar the configuration of the light emitting device 1000, the description of the configuration of the light emitting device 1000B may be omitted.

FIG. 18 is a schematic cross-sectional view showing a configuration of the light emitting device 1000B according to an embodiment of the present invention.

As shown in FIG. 18, the light emitting device 1000B includes the ScAlMgO₄ substrate 1011, a glass substrate 1110B, the undoped nitride semiconductor layer 1030, the n-type nitride semiconductor layer 1040, the light emitting layer 1050, the p-type nitride semiconductor layer 1060, the protective layer 1070, the n-type electrode 1080, and the p-type electrode 1090.

The glass substrate 1110B is provided on the first surface 1011_1 of the ScAlMgO₄ substrate 1011 through an adhesive layer 1120B. The adhesive layer 1120B can fix the glass substrate 1110B to the ScAlMgO₄ substrate 1011. For example, an acrylic adhesive or an epoxy adhesive can be used for the adhesive layer 1120B. The light emitting device 1000B can be manufactured by applying an acrylic adhesive or the like to the first surface 1011_1 of the ScAlMgO₄ substrate 1011 exposed by cleavage as shown in FIG. 13, and then bonding the glass substrate 1110B to the ScAlMgO₄ substrate 1011. The surface of the glass substrate 1110B has a concave-convex pattern. The concave-convex pattern may be formed before or after bonding the glass substrate 1110B.

Although the glass substrate 1110B is generally amorphous and does not have a crystalline structure, a crystalline structure may exist in a minute region. The upper limit of the thermal expansion coefficient of the glass substrate 1110B is less than 4.2×10−6/K, preferably less than 4.0×10−6/K. The lower limit of the thermal expansion coefficient of the glass substrate 1110B is greater than 3.0×10−6/K, preferably greater than 3.5×10−6/K. It is preferable that the glass substrate 1110B has a low alkali metal content to prevent contamination of the light emitting layer 1050. For example, the alkali metal content in the glass substrate 1110B is less than or equal to 0.1 mass %. For example, an amorphous glass material composed of aluminoborosilicate glass or aluminosilicate glass can be used for the glass substrate 1110B.

The thickness of the glass substrate 1110B is not limited to a certain value. However, from the viewpoint of reducing warpage of the ScAlMgO₄ substrate 1011, it is preferable that the thickness of the glass substrate 1110B is sufficiently greater than the total film thickness of the ScAlMgO₄ substrate 1011, the undoped nitride semiconductor layer 1030, the n-type nitride semiconductor layer 1040, the light emitting layer 1050, and the p-type nitride semiconductor layer 1060. For example, the thickness of glass substrate 1110B is 50 times greater than or equal to the total film thickness of the undoped nitride semiconductor layer 1030, the n-type nitride semiconductor layer 1040, the light emitting layer 1050, and the p-type nitride semiconductor layer 1060. Specifically, the thickness of the glass substrate 1110B is greater than or equal to 0.5 mm and less than or equal to 1.0 mm.

In the present embodiment, light emitted from the light emitting layer 1050 passes through the n-type nitride semiconductor layer 1040, the undoped nitride semiconductor layer 1030, the ScAlMgO₄ substrate 1011, and the adhesive layers 1120B and 1110B before being emitted to the outside. The refractive indexes of the layers through which light passes can be set in the approximately smaller order of 2.3 (refractive index of the n-type nitride semiconductor layer 1040 and the undoped nitride semiconductor layer 1030), 1.9 (refractive index of the ScAlMgO₄ substrate 1011), 1.52 to 1.55 (refractive index of the adhesive layer 1120B), and 1.51 (glass substrate 1110B). Further, the concave-convex pattern that improves light extraction efficiency is formed on the surface of the glass substrate 1110B. Therefore, the light extraction efficiency of the light emitting device 1000B according to the present embodiment is improved. Further, the rigidity of the light emitting device 1000B can be increased by providing the glass substrate 1110B.

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A light emitting device, comprising:
a ScAlMgO₄ substrate comprising a first surface and a second surface opposite the first surface;
an undoped nitride semiconductor layer over the second surface of the ScAlMgO₄ substrate; and
a light emitting layer over the undoped nitride semiconductor layer,
wherein the light emitting layer has an MQW structure in which well layers containing InₓGa₍₁₋ₓ₎N (0.30≤x≤0.50) and barrier layers containing In_{y}In_{y}Ga_{(1-y)}N (0<y<x) are alternately stacked, and
wherein a concave-convex pattern is provided over the first surface.

2. The light emitting device according to claim 1, wherein the undoped nitride semiconductor layer is in contact with the second surface of the ScAlMgO₄ substrate.

3. The light emitting device according to claim 1, wherein a height of the concave-convex pattern is higher than or equal to 1 μm and lower than or equal to 3 μm.

4. The light emitting device according to claim 1, wherein a thickness of the ScAlMgO₄ substrate is greater than or equal to 5 μm and less than or equal to 10 μm.

5. The light emitting device according to claim 1, wherein the concave-convex pattern is formed on the first surface of the ScAlMgO₄ substrate.

6. The light emitting device according to claim 1, further comprising an optical adjustment layer over the first surface of the ScAlMgO₄ substrate,
wherein a refractive index of the optical adjustment layer is smaller than a refractive index of the ScAlMgO₄ substrate, and
wherein the concave-convex pattern is formed on the optical adjustment layer.

7. The light emitting device according to claim 1, further comprising a glass substrate bonded to the first surface of the ScAlMgO₄ substrate,
wherein the concave-convex pattern is formed on the glass substrate.

8. A method for manufacturing a light emitting device, comprising the steps of:
forming an degassing prevention layer over a first surface of a ScAlMgO₄ support substrate;
forming an undoped nitride semiconductor layer over a second surface of the ScAlMgO₄ support substrate opposite the first surface; and
forming a light emitting layer having an MQW structure by alternately depositing well layers containing InₓGa₍₁₋ₓ₎N (0.30≤x<0.50) and barrier layers containing In_{y}In_{y}Ga_{(1-y)}N (0<y<x) over the undoped nitride semiconductor layer using sputtering.

9. The method for manufacturing a light emitting device according to claim 8, wherein the undoped nitride semiconductor layer is formed by sputtering.

10. The method for manufacturing a light emitting device according to claim 8, further comprising a step of cleaving the ScAlMgO₄ support substrate to remove the degassing prevention layer.

11. The method for manufacturing a light emitting device according to claim 10, further comprising a step of forming a concave-convex pattern over a third surface exposed by cleaving the ScAlMgO₄ support substrate.

12. The method for manufacturing a light emitting device according to claim 10, further comprising a step of forming an optical adjustment layer over a third surface exposed by cleaving the ScAlMgO₄ support substrate,
wherein a refractive index of the optical adjustment layer is smaller than a refractive index of the ScAlMgO₄ substrate.

13. The method for manufacturing a light emitting device according to claim 12, further comprising a step of forming a concave-convex pattern on the optical adjustment layer.

14. The method for manufacturing a light emitting device according to claim 10, further comprising a step of bonding a glass substrate to a third surface exposed by cleaving the ScAlMgO₄ support substrate.

15. The method for manufacturing a light emitting device according to claim 14, wherein the glass substrate before being bonded to the third surface comprises a concave-convex pattern.

16. The method for manufacturing a light emitting device according to claim 10,
wherein the step of cleaving the ScAlMgO₄ support substrate comprises:
forming a notch in an edge surface of the ScAlMgO₄ support substrate, and
applying a compressive pressure to the edge surface of the ScAlMgO₄ support substrate.
